(19) United States
(12) Patent Application Publication
(10) Pub. No.: US 2007/0284712 A1
(43) Pub. Date: Dec. 13, 2007

(54) Semiconductor integrated circuit device, and method of designing and manufacturing the same

(75) Inventor: Masato Inoue, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/798,165

(22) Filed: May 10, 2007

(30) Foreign Application Priority Data
Jun. 13, 2006 (JP) 2006-163528

(51) Int. Cl. H01L 23/48; H01L 21/00

(52) U.S. Cl. 257/678; 438/106; 438/612; 257/734

(57) ABSTRACT

Disclosed are a semiconductor integrated circuit device, and a design and manufacturing method of the device, in which various semiconductor integrated circuit devices can be effectively designed and manufactured at low cost using a master slice method. A fixed layer used in common between Wire-Bonding (WB) chips and Flip-Chip (FC) chips is previously designed. When it is determined whether to form a WB chip or a FC chip, a variable layer for the WB chip or for the FC chip is designed. Based on this design, the WB chip or FC chip including the fixed layer and the variable layer added thereto is formed. Since the WB chip and the FC chip are differentially formed by the variable layer, the designing and manufacturing man-hour can be concentrated on the variable layer. Thus, reduction in TAT and in cost can be realized in design and manufacture of the device.

### CROSS-REFERENCE TO RELATED APPLICATIONS

This application is based upon and claims the benefits of priority from the prior Japanese Patent Application No. 2006-163528 filed Jun. 13, 2006, the entire contents of which are incorporated herein by reference.

### BACKGROUND OF THE INVENTION

1. Field of the Invention

The present invention relates to a method of designing a semiconductor integrated circuit device, to a semiconductor integrated circuit device and to a method of manufacturing the same. More particularly, the present invention relates to a method of designing a semiconductor integrated circuit device using a master slice method. The present invention also relates to a semiconductor integrated circuit device formed using a master slice method and a method of manufacturing the same.

2. Description of the Related Art

In design of a semiconductor integrated circuit device, a master slice method may be employed for reduction in Turn Around Time (TAT) and in cost.

In the master slice method, a wafer is divided into a first layer (fixed layer) where a main Intellectual Property (IP) macro and a basic wiring layer are made common between different varieties, and a second layer (variable layer) where customization of a wiring structure is allowed. To the fixed layer previously designed, a variable layer is newly added and as a result, a desired architecture is completed.

In design of the semiconductor integrated circuit device using the master slice method, a common design resource can be used between different predetermined varieties. Therefore, the design and the manufacture of the semiconductor integrated circuit device based on the design can be effectively performed at low cost. Accordingly, the master slice method is currently used widely for development of Application Specific Integrated Circuit (ASIC).

As for a design approach of the semiconductor integrated circuit device, various proposals are heretofore disclosed to realize efficiency of the design approach as well as high performance, miniaturization and cost reduction of chips.

For example, the following method is proposed. In arranging pads or bumps in the outermost periphery of a chip, input-output buffers (IO) in the inner side thereof and internal circuits (core) in the remaining inner region thereof, the core is designed with the IO, whereby an empty space resulting from imbalance between the number of IOs and the core size is reduced without changing a basic algorithm of a design tool (see, e.g., Japanese Unexamined Patent Publication No. Hei 09-69568). In addition to the arrangements of chip terminals, IOs and a core, this proposal also discloses a laying method of power supply wires, ground wires, surrounding power supply wires (core rings) and core power supply wires after the arrangements thereof.

In the design of a semiconductor integrated circuit device using the conventional master slice method, a common design resource can be used between different predetermined varieties as described above. However, this method assumes that a common design resource is used between the varieties within the packages of the same type, as in the case where the varieties are Wire-Bonding (WB) chips or Flip-Chip (FC) chips.

Accordingly, in the conventional master slice method, a common design resource can be used in each case between different WB chips and between different FC chips. However, a common design resource is unable to be used between the WB chip and the FC chip which are different in package types and different in architectures (power architectures) of elements related to a power supply of the chip, such as pads and IOs.

FIG. 7 is an essential-part plan view of a chip. FIG. 8 illustrates a conventional power architecture of a WB chip. FIG. 9 illustrates a conventional power architecture of an FC chip.

Assume as the semiconductor integrated circuit device, for example, a chip including a core 100 and peripheral regions 101 of the core as shown in FIG. 7. Predetermined circuits including core rings are formed in the core 100, and elements such as pads and IOs related to a power supply of the chip are arranged in the peripheral regions 101. Here, the power architecture of such a chip is taken notice of.

Assume, for example, as shown in FIGS. 8 and 9, that the chip comprises a multilayer structure including on a semiconductor substrate a bulk layer where a diffusion layer is formed, and the first to sixth wiring layers and uppermost wiring layer where wires are formed. Further, assume that such a chip is formed using the master slice method. Here, there is illustrated, for example, a case where layers of the bulk layer to the second wiring layer are designed as a fixed layer 200 used in common between the WB chip and the FC chip, and layers of the third wiring layer to the uppermost wiring layer are designed as variable layers 201 and 202 which can be changed in the WB chip and the FC chip, respectively.

The power architecture of the WB chip is designed as follows. As shown in FIG. 8, a pad region 200a, an IO region 200b and a pad-IO wiring region 200c therebetween are provided in the fixed layer 200′. To correspond to the respective regions of the fixed layer, a pad region 201a, an IO region 201b and a pad-IO wiring region 201c therebetween are provided in the variable layer 201.

In this power architecture of the WB chip, the pad regions 200a and 201a are regions where pads of the WB chip are formed. The IO regions 200b and 201b are regions where IOs of the WB chip are formed. The pad-IO wiring regions 200c and 201c are regions where pad-IO wires for electrically connecting between the pads and IOs of the WB chip are formed.

The constitutions of the pad region 201a, IO region 201b and pad-IO wiring region 201c of the variable layer 201 are designed based on the constitutions of the pad region 200a, IO region 200b and pad-IO wiring region 200c of the fixed layer 200, respectively. The respective elements such as pads, IOs and pad-IO wires are formed in both of the fixed layer 200 and the variable layer 201.

On the other hand, the power architecture of the FC chip is designed as follows. As shown in FIG. 9, a pad region 200a, an IO region 200b and a pad-IC wiring region 200c therebetween are provided in the fixed layer 200 similarly to the WB chip. To correspond to the respective regions of the fixed layer, a pad region 202a, an region 202b and a pad-IO wiring region 202c therebetween are provided in the variable layer 202. Further, a bump and wiring region connected to the bump 202d is provided over the IO region 202b of the variable layer 202.

In this power architecture of the FC chip, the pad regions 200a and 202a are regions where pads of the FC chip are formed. The IC regions 200b and 202b are regions where IOs of the FC chip are formed. The pad-IO wiring regions 200c and 202c are regions where pad-IO wires for electrically connecting between the pads and IOs of the FC chip are formed.

The constitutions of the pad region 202a, IO region 202b and pad-IO wiring region 202c of the variable layer 202 are designed based on the constitutions of the pad region 200a, IO region 200b and pad-IO wiring region 200c of the fixed layer 200, respectively. Further, a constitution of the bump and wiring region connected to the bump 202d of the variable layer 202 is designed based on the constitution of the IO region 202b beneath the region 202d. Also in the case of the FC chip, the respective elements such as pads, IOs and pad-IO wires are formed in both of the fixed layer 200 and the variable layer 202, similarly to the case of the WB chip.

In reality, formation of bumps as in the power architecture of the FC chip is not required in the power architecture of the WB chip. Therefore, in the case of the WB chip, a portion corresponding to the bump and wiring region connected to the bump 202d of the FC chip is allocated to the IO region 201b, as shown in FIGS. 8 and 9. More specifically, in forming the power architecture, a design resource of the WB chip is unable to be directly applied to that of the FC chip which requires the formation of bumps. On the contrary, a design resource of the FC chip which requires the formation of bumps is unable to be directly applied to that of the WB chip which requires no formation of bumps.

Further, formation of pads as in the power architecture of the WB chip may not be required in the power architecture of the FC chip. However, since the pads are formed in both of the fixed layer 200 and the variable layer 201 or 202 as shown in FIGS. 8 and 9, and are formed first from the fixed layer 200, the following problems occur. In the case where the fixed layer 200 having the pad region 200a is used in common between the WB chip and the FC chip, even if the pads are not required in the FC chip, it is difficult to remove the pads. Also in the case of the WB chip, since the pads are formed in both of the fixed layer 200 and the variable layer 201 as described above, it is difficult to remove a part of the pads or to change the arrangement of the pads.

Thus, in the conventional design method using the master slice method, when package types are different as in the case between the WB chip and the FC chip, a common design resource is unable to be directly used therebetween. Therefore, even if the main functions of chips are the same as in the case between the WB chip and the FC chip, the design must be performed using the respective design resources. As a result, increase in TAT and in cost is caused.

In the case where different power architectures are designed even when package types are the same, the following problem occurs. Since the pads are formed in both of the fixed layer and the variable layer, the power architecture of the variable layer, such as the presence/absence or arrangement of pads, is restricted by the power architecture of the fixed layer and as a result, the degree of design freedom is reduced.

### SUMMARY OF THE INVENTION

In view of the foregoing, it is an object of the present invention to provide a method of designing a semiconductor integrated circuit device, in which various semiconductor integrated circuit devices can be effectively designed at low cost regardless of a package type.

It is another object of the present invention to provide the thus designed semiconductor integrated circuit device and a method of manufacturing the same.

To accomplish the above objects, according to one aspect of the present invention, there is provided a method of designing a semiconductor integrated circuit device. This method comprises the steps of: designing a first layer which constitutes a portion including no pads of the device, the first layer being used in common regardless of a package type of the device; and designing depending on the package type a second layer which constitutes a portion over the first layer of the device.

According to another aspect of the present invention, there is provided a semiconductor integrated circuit device. This device comprises: a first layer which constitutes a portion including no pads of the device, the first layer being used in common regardless of a package type of the device; and a second layer which constitutes a portion over the first layer of the device, the second layer being formed depending on the package type.

According to yet another aspect of the present invention, there is provided a manufacturing method of a semiconductor integrated circuit device. This method comprises the steps of: forming a first layer which constitutes a portion including no pads of the device, the first layer being used in common regardless of a package type of the device; and forming depending on the package type a second layer which constitutes a portion over the first layer of the device.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows a design flow of a semiconductor integrated circuit device.

FIG. 2 illustrates a power architecture of a WB chip.

FIG. 3 illustrates a power architecture of an FC chip.

FIG. 4 is an essential-part plan view of a common portion of the WB chip and the FC chip.

FIG. 5 is an essential-part plan view of a power architecture of the WB chip.

FIG. 6 is an essential-part plan view of a power architecture of the FC chip.

FIG. 7 is an essential-part plan view of a chip.

FIG. 8 illustrates a conventional power architecture of the WB chip.

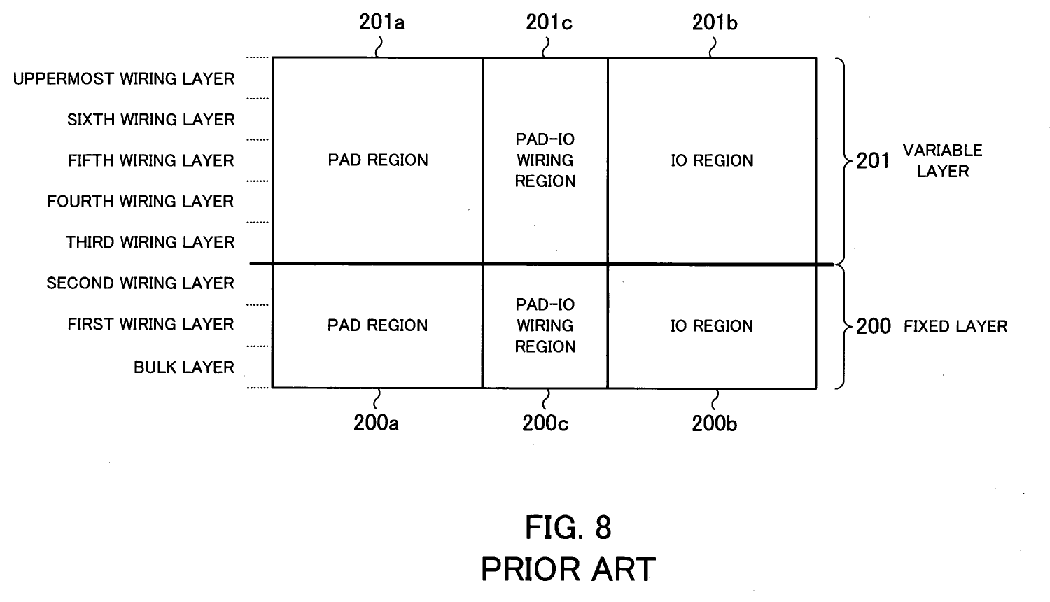

FIG. 9 illustrates a conventional power architecture of the FC chip.

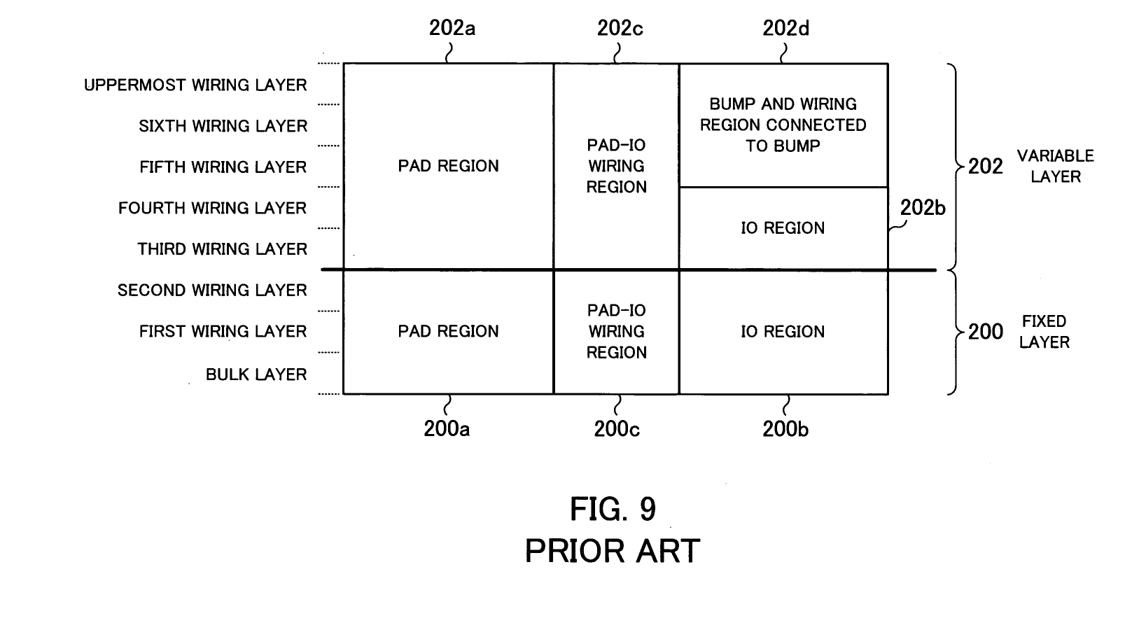

### DESCRIPTION OF THE PREFERRED EMBODIMENTS

Preferred embodiments of the present invention will be described in detail below with reference to the accompanying drawings, wherein like reference numerals refer to like elements throughout.

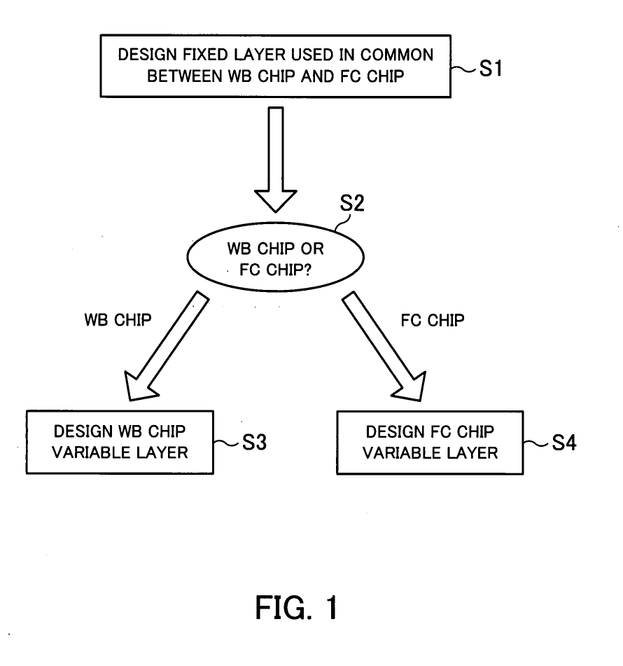

FIG. 1 shows a design flow of a semiconductor integrated circuit device.

Here, the semiconductor integrated circuit device such as a WB chip and an FC chip is designed using a master slice method. A fixed layer is designed in common between the WB chip and the FC chip. At the same time, differential formation of the WB chip and the FC chip is performed in the variable layer.

First, the fixed layer used in common between the WB chip and the FC chip is previously designed (step S1). The fixed layer constitutes a portion which can be used in common between the WB chip and the FC chip regardless of the constitution of the variable layer provided over the fixed layer. Note, however, that a region for forming pads is excluded from the fixed layer in this case. Then, it is determined whether to form the WB chip or to form the FC chip using the fixed layer (step S2). In the case of forming the WB chip, the variable layer for the WB chip is designed (step S3). In the case of forming the FC chip, the variable layer for the FC chip is designed (step S4).

Based on the thus performed design, the WB chip or FC chip having such a fixed layer and a variable layer is formed. In this case, for example, there can be employed the following method. Formation of the fixed layer is previously completed. Then, it is determined whether a product formed using the fixed layer is the WB chip or the FC chip. At this stage, design and formation of the variable layer is performed in accordance with the determination.

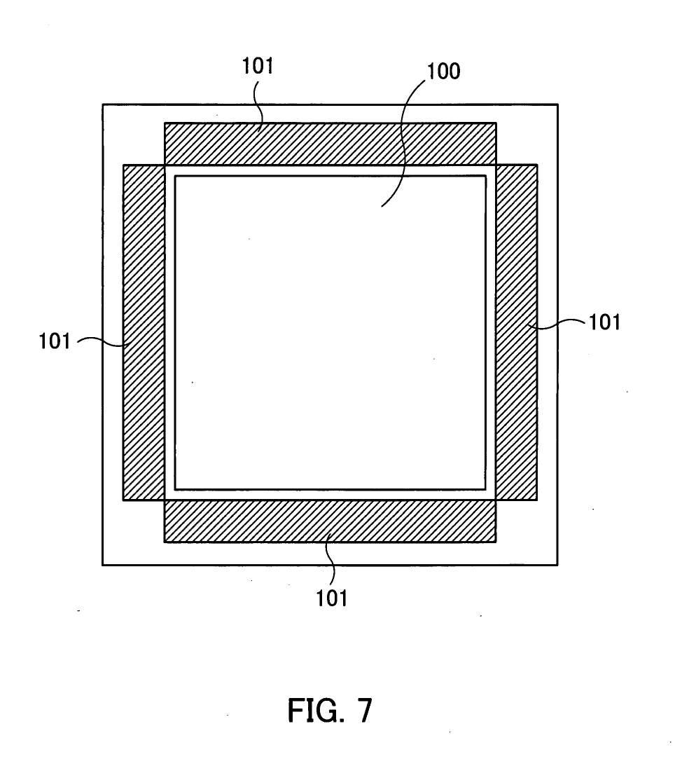

The design of the WB chip and the FC chip as well as the power architecture formed based on this design will be described. Assume herein a case where the WB chip and the FC chip have a chip structure as shown in FIG. 7.

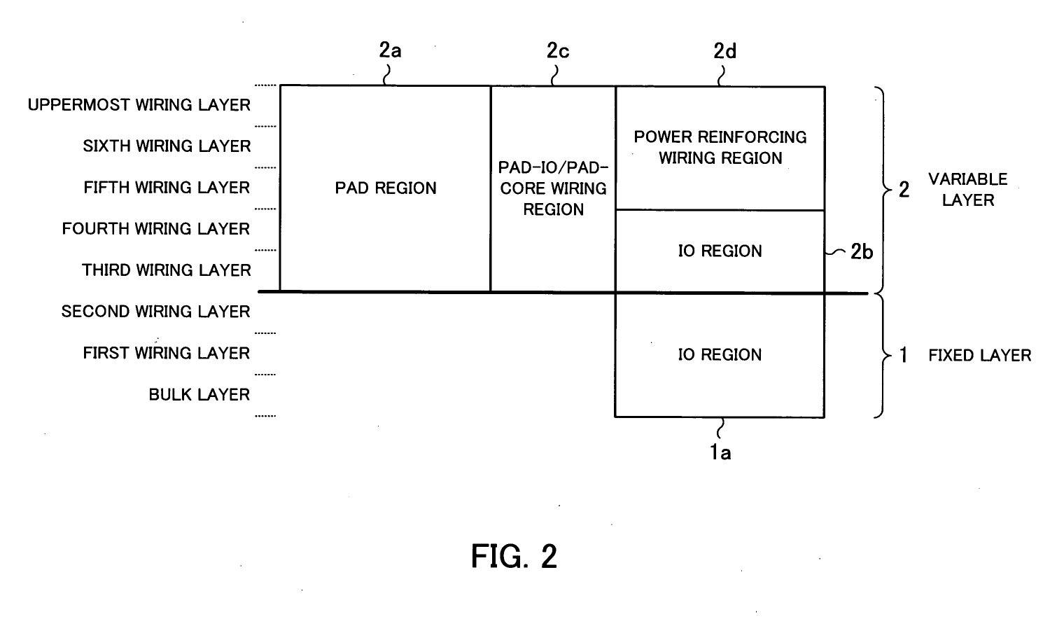

FIG. 2 illustrates the power architecture of the WB chip.

Assume, for example, a case where the WB chip comprises a multilayer structure including on a semiconductor substrate a bulk layer where a diffusion layer is formed, and the first to sixth wiring layers and uppermost wiring layer where wires are formed. FIG. 2 illustrates a case where layers of the bulk layer to the second wiring layer are designed as a fixed layer 1 which is a first layer, and layers of the third wiring layer to the uppermost wiring layer are designed as a variable layer 2 which is a second layer.

The power architecture of the WB chip shown in FIG. 2 is designed as follows. An IO region 1a is provided in the fixed layer 1. A pad region 2a, an region 2b, a pad-IO/pad-core wiring region 2c and a power reinforcing wiring region 2d are provided in the variable layer 2.

The IO region 1a of the fixed layer 1 is a region where all or part of the IOs of the WB chip is formed. The IO region 2b of the variable layer 2 is a region where a part of the IOs of the WB chip or occasionally the IOs and the wires (IO rings) for electrically connecting between the IOs are formed.

The pad region 2a of the variable layer 2 is a region where pads of the WB chip are formed. The pad-IO/pad-core wiring region 2c of the variable layer 2 is a region where a part of the pad-IO wire for electrically connecting between the pads and IOs of the WB chip, and a part of the pad-core wire for electrically connecting between the pads and a core (not shown) of the WB chip are formed. The pad-core wire is formed also in the power reinforcing wiring region 2d and serves as a wire for reinforcing the power supply between the pads and the core. The above-described IO rings may be formed in the IO region 2b of the variable layer 2 as described above as well as formed in this region 2d.

In the case of the WB chip, the need for the above-described power supply reinforcement is increasing in terms of the structure as compared with the FC chip. By providing the power reinforcing wiring region 2d as shown in FIG. 2, even if various wires for the power supply reinforcement are required, easy response to the requirement is allowed.

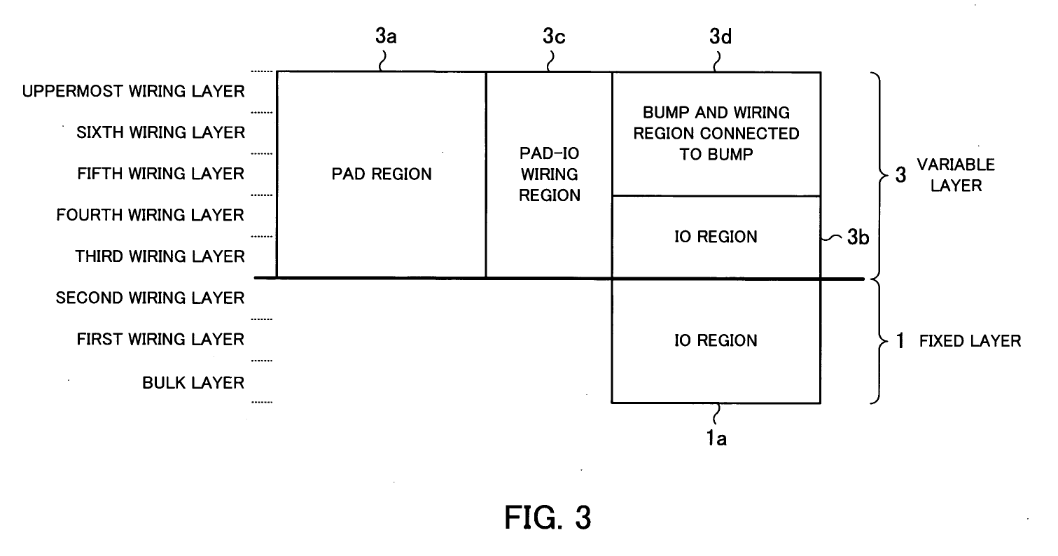

FIG. 3 illustrates the power architecture of the FC chip.

Similarly to the WB chip, assume a case where the FC chip comprises a multilayer structure including on a semiconductor substrate the bulk layer, the first to sixth wiring layers and the uppermost wiring layer. FIG. 3 illustrates a case where layers of the bulk layer to the second wiring layer are designed as the fixed layer 1 used in common with the WB chip, and layers of the third wiring layer to the uppermost wiring layer are designed as the variable layer 3.

The power architecture of the FC chip shown in FIG. 3 is designed as follows. In the variable layer 3, a pad region 3a, an IO region 3b and a pad-IO wiring region 3c are provided similarly to the variable layer 2 of the WB chip and at the same time, a bump and wiring region connected to the bump 3d is provided in a region to which the power reinforcing wiring region 2d is allocated in the variable layer 2 of the WB chip.

The pad region 3a is a region where, in the case of forming pads on the FC chip, the pads are formed. The IO region 3b is a region where a part of the IOs of the FC chip are formed. The pad-IO wiring region 3c is a region where, in the case of forming the pads on the FC chip, a pad-IC wire for electrically connecting the pads and the IOs is formed. The bump and wiring region connected to the bump 3d is a region where the bumps of the FC chip and the wires including the connection between the bumps and the IOs are formed.

In the case of the FC chip, the power architecture may be designed such that when the formation of pads is not required, the pads and pad-IO wires are not formed in the variable layer 3. In this power architecture of the FC chip, only the IOs are formed in the fixed layer 1. Therefore, without being affected by the constitution of the fixed layer 1, the variable layer 3 can be easily changed to a constitution where the pads and pad-IO wires are not formed.

In each case of the WB chip and of the FC chip, the power architecture may be designed such that the IOs are not formed in the variable layers 2 and 3. In this case, the IOs of the WB chip and the FC chip are formed only in the IO region 1a of the fixed layer 1. In the IO regions 2b and 3b of the variable layers 2 and 3, a part of the pad-IO wires which lead out of the pad-IO/pad-core wiring region 2c and the pad-IO wiring region 3c are formed, respectively. As described above, the IO rings may be formed in the IO region 2b in the case of the WB chip.

As shown in FIGS. 2 and 3, the power architectures of the WB chip and the FC chip are designed and formed such that the respective regions of the pad regions 2a and 3a, the IO regions 2b and 3b, the pad-IO/pad-core wiring region 2c and pad-IO wiring region 3c, and the power reinforcing wiring region 2d and the bump and wiring region connected to the bump 3d are arranged to correspond to each other between the variable layers 2 and 3.

Further, rules as shown below are herein applied to constitute the power architectures as shown in FIGS. 2 and 3.

The first rule is as follows. In the case of the WB chip, the pad region 2a is provided in a region including the uppermost wiring layer of the variable layer 2, and a region for forming the pads is not provided in the fixed layer 1. In other words, the pads of the WB chip are formed only in the variable layer 2.

In the case of the FC chip, when the pads are formed, the pad region 3a is provided in a region including the uppermost wiring layer of the variable layer 3 and a region for forming the pads is not provided in the fixed layer 1, similarly to the case of the WB chip.

By applying the rule described above, the following advantages are obtained. As to the WB chip, a shape or arrangement of the pad can be freely set without being affected by the constitution of the fixed layer 1. As to the FC chip, selection whether to form the pads can be made. In the case of forming the pads, a shape or arrangement of the pad can be freely set without being affected by the constitution of the fixed layer 1.

The second rule is as follows. The IOs are formed only in the fixed layer 1. Alternatively, in the case of the WB chip, the IOs are formed in both of the fixed layer 1 and variable layer 2 as shown in FIG. 2. In the case of the FC chip, the IOs are formed in both of the fixed layer 1 and variable layer 3 as shown in FIG. 3.

When the IOs are formed only in the fixed layer 1, the need for the IO regions 2b and 3b of the variable layers 2 and 3 to be used in formation of the IOs is eliminated and as a result, the degree of design freedom of the variable layers 2 and 3 can be increased. When the IOs are formed in both of the fixed layer 1 and the variable layer 2 or 3, customization of the IOs is allowed in the variable layer 2 or 3.

The third rule is as follows. In the case of the WB chip, some regions of the variable layer 2 are designed as the pad-IO/pad-core wiring region 2c and the power reinforcing wiring region 2d as shown in FIG. 2, whereby the wire for the power reinforcing between the pad and the core is formed in the variable layer 2.

On this occasion, the power reinforcing wiring region 2d is provided in an upper layer over the IO region 2b, whereby the power reinforcing wire between the pad and the core is formed in an upper layer over the IO.

The forth rule is as follows. In the case of the WB chip, some regions of the variable layer 2 are designed as the pad-IO/pad-core wiring region 2c as shown in FIG. 2, whereby the pad-IO wire is formed only in the variable layer 2.

As described above, when the pads are formed only in the variable layer 2, a shape or arrangement of the pads can be freely set (first rule). Therefore, when the pad-IO wire is formed only in the variable layer 2, the wire with a high degree of freedom can be formed to fit on a shape or arrangement of the pads.

The fifth rule is as follows. In the case of the FC chip, some regions of the variable layer 3 are designed as the bump and wiring region connected to the bump 3d as shown in FIG. 3.

On this occasion, the bump and wiring region connected to the bump 3d is provided in a region including the uppermost wiring layer of the variable layer 3, whereby the bump is formed in an upper layer over the IO.

Thus, in designing the power architecture, the respective formation regions of the pads, IOs and pad-IO wires within the variable layers are arranged to correspond to each other between the WB chip and the FC chip. At the same time, the formation region of the power reinforcing wire and that of the bump are arranged to correspond to each other between the upper layer portions within the variable layers, thereby leaving the degree of freedom capable of arranging in the upper layer portion the power reinforcing wire or the bump depending on whether to form the WB chip or to form the FC chip. As to the respective regions, the above-described different rules are applied depending on whether to form the WB chip or to form the FC chip. Thus, the respective power architectures of the WB chip and the FC chip are designed. Based on the designs, the respective power architectures are formed.

As a result, the WB chip and the FC chip can be differentially formed by the variable layer using a common design resource. Therefore, reduction in TAT and in cost can be realized in the design and manufacture of the WB chip and the FC chip.

Further, the pads are formed only in the variable layer, and the fixed layer is not used in formation of the pad. Therefore, in the case of the WB chip, a shape or arrangement of the pads can be set with a high degree of freedom. In the case of the FC chip, selection whether to form the pads can be made. When the pads are not formed, reduction in the chip size can be realized. When the pads are formed in the FC chip, a shape or arrangement of the pads can be set with a high degree of freedom similarly to the case of the WB chip.

Next, the WB chip and FC chip designed using the above design method as well as the forming method of the same will be described in detail. Here, assume as the WB chip and the FC chip a chip having a structure as shown in FIG. 7.

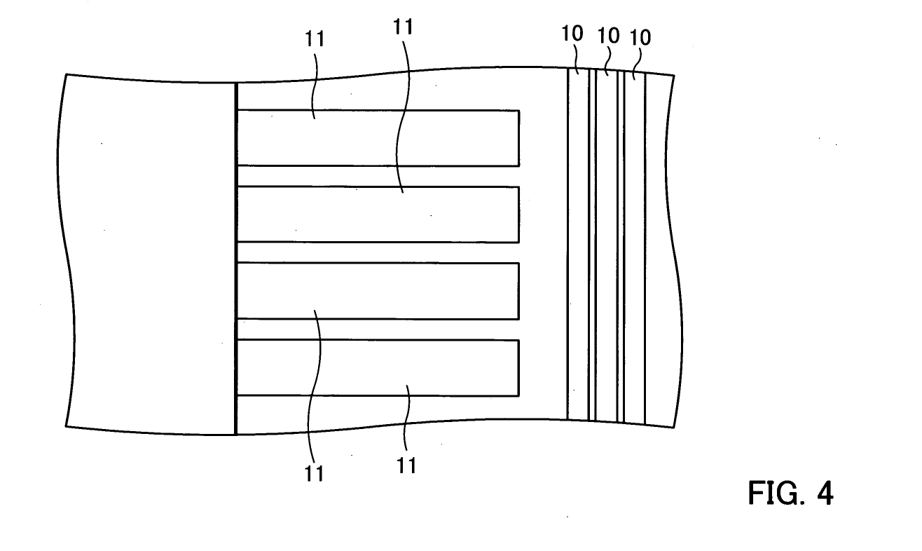

FIG. 4 is an essential-part plan view of a common portion of the WB chip and the FC chip.

As shown in FIG. 4, a portion used in common between the WB chip and the FC chip, namely, the fixed layer has a constitution where IOs 11 are arranged side by side near core rings 10 formed at the edge of the core.

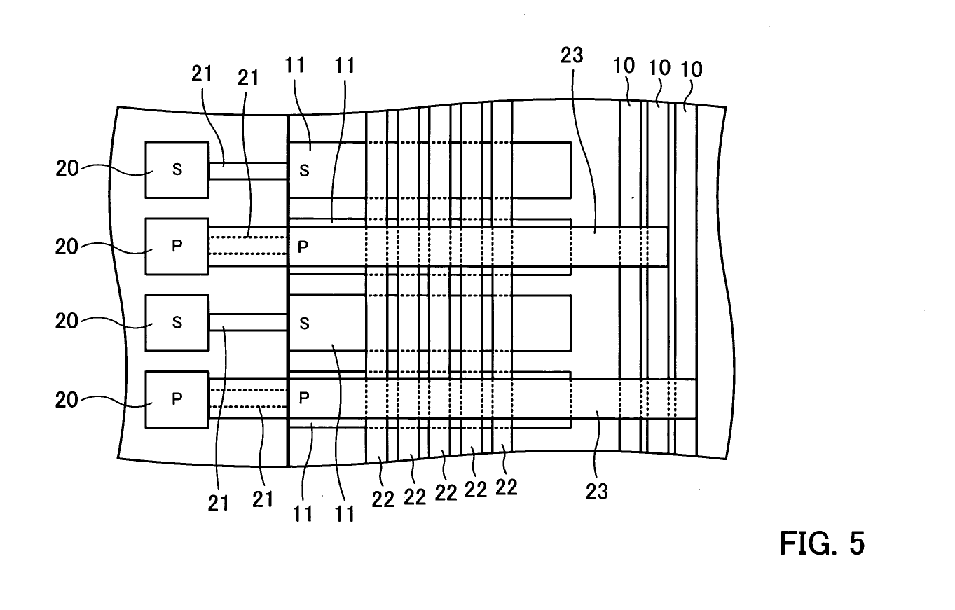

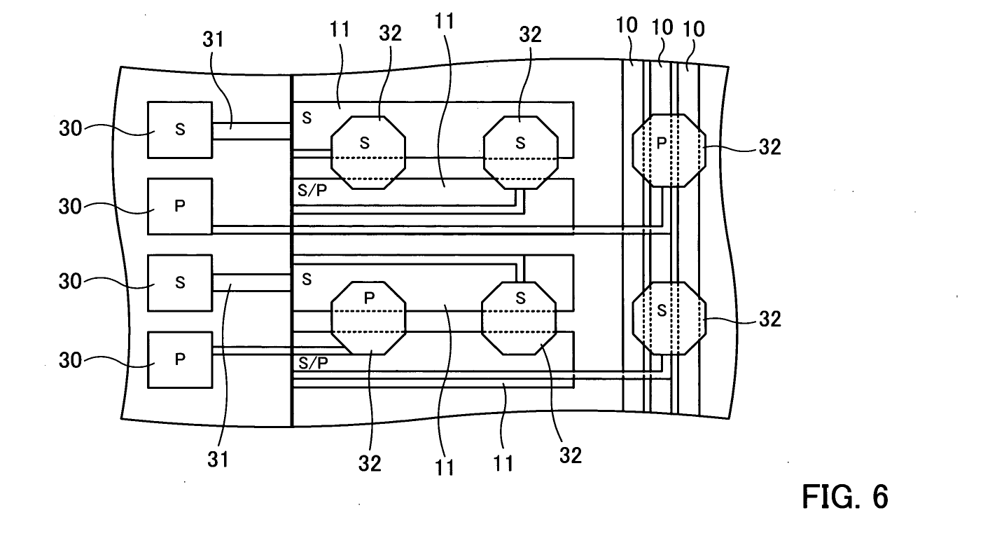

Starting from the stage of the fixed layer having such a constitution, the power architecture of the WB chip or the FC chip is formed in the variable layer. In this case, the respective power architectures of the WB chip and the FC chip can be designed to have the constitutions, for example, as shown in the next FIGS. 5 and 6, respectively.

FIG. 5 is an essential-part plan view of the power architecture of the WB chip.

The power architecture of the WB chip has the following constitution. Near the IO 11 on the side opposite to the core ring 10 side, the signal (S) pad 20 and the power supply (P) pad 20 are arranged side by side facing the respective IOs 11. Each of the respective signal (S) pads 20 and power supply (P) pads 20 is connected to the facing IO 11 through the pad-IO wire 21. Over the IO 11, the IO ring 22 is formed for reinforcing a power supply. Between the power supply (P) pad 20 and the core ring 10, the pad-core wire 23 is formed similarly for reinforcing a power supply.

In the power architecture of the WB chip having such a constitution, any of the pad 20, the pad-IO wire 21, the IO ring 22 and the pad-core wire 23 are formed in the variable layer provided over the fixed layer shown in FIG. 4.

The pad 20 is formed in a region including the uppermost wiring layer of the variable layer. The pad-IO wire 21 electrically connects through the variable layer the pad 20 formed in the variable layer and the IO 11 formed in the fixed layer. The IO ring 22 is formed in a region within the variable layer over the IO 11 formed in the fixed layer. The pad-core wire 23 is formed in a region within the variable layer over the IO 11 formed in the fixed layer and over the IC ring 22 formed in the variable layer.

Each of the pad 20, the pad-IO wire 21, the IO ring 22 and the pad-core wire 23 is formed in one layer or across plural layers constituting the variable layer. A circuit designer, while taking the constitution of the fixed layer into consideration, designs the layers used in formation of the pad 20, the pad-IO wire 21, the IC ring 22 and the pad-core wire 23 as well as designs a shape or arrangement of each element, for example, within the predetermined number of variable layers. Based on this design, the WB chip having the power architecture as shown in FIG. 5 is formed. In this case, there can be employed the following method. Formation of the fixed layer is previously completed. When the formation of the WB chip is determined, the variable layer having the above-described constitution is designed and formed.

FIG. 6 is an essential-part plan view of the power architecture of the FC chip.

The power architecture of the FC chip has the following constitution. Near the IO 11 on the side opposite to the core ring 10 side, the signal (S) pad 30 and the power supply (P) pad 30 are arranged side by side facing the respective IOs 11, if desired. In this case, the signal (S) pad 30 is electrically connected to the facing IO 11 through the pad-IO wire 31. The power supply (P) pad 30 is connected to the power supply (P) bump 32 formed in the predetermined positions over the IO 11 and over the core ring 10.

Regardless of the presence/absence of the pad 30 and the pad-IO wire 31, the signal (S) bump 32 and the power supply (P) bump 32 are formed in the predetermined positions over the IO 11.

In the power architecture of the FC chip having such a constitution, any of the pad 30, the pad-IO wire 31 and the bump 32 are formed in the variable layer provided over the fixed layer shown in FIG. 4.

The pad 30 is formed in a region including the uppermost wiring layer of the variable layer. The pad-IO wire 31 electrically connects through the variable layer the pad 30 formed in the variable layer and the IO 11 formed in the fixed layer. The bump 32 is formed in a region within the variable layer over the IO 11 formed in the fixed layer.

Each of the pad 30, the pad-IO wire 31 and the bump 32 is formed in one layer or across plural layers constituting the variable layer. A circuit designer, while taking the constitution of the fixed layer into consideration, designs layers used in formation of the pad 30, the pad-IO wire 31 and the bump 32 as well as designs a shape or arrangement of each element, for example, within the predetermined number of variable layers. Based on this design, the FC chip having the power architecture as shown in FIG. 6 is formed. In this case, there can be employed the following method. Formation of the fixed layer is previously completed. When the formation of the FC chip is determined, the variable layer having the above-described constitution is designed and formed.

As described above, in the design and manufacture of the semiconductor integrated circuit device using the master slice method, the fixed layer is designed in common between different varieties as well as differential formation of these varieties is performed by the variable layer using a common design resource. Therefore, the designing and manufacturing man-hour can be concentrated on the variable layer in both cases where the package types are the same and where the package types are different, that is, regardless of the package type. As a result, reduction in TAT and in cost can be realized in the design and manufacture of the device.

In this case, the pads are formed not in the fixed layer but in the variable layer. Therefore, selection whether to form the pads can be made. In the case of forming the pads, a shape or arrangement of the pads can be set freely. As a result, miniaturization, optimum arrangement/wiring, and cost reduction of the semiconductor integrated circuit device can be realized.

In the above description, the total number of layers constituting the semiconductor integrated circuit device, and the respective numbers of the layers constituting the fixed layer and variable layer of the device are mere examples and not limited to the above number. These numbers of layers can be arbitrarily set depending on the function, usage, designing/manufacturing cost and package type of the device.

In the present invention, the first layer which constitutes a portion including no pads of the semiconductor integrated circuit device is designed in common regardless of a package type of the device, and the second layer which constitutes a portion over the first layer is designed depending on a package type. As a result, the semiconductor integrated circuit devices having different package types can be differentially formed by the second layer. Further, the optimum arrangement/wiring can be performed by the second layer regardless of the package type as well as flexible actions can be made to various design changes. Thus, the designing and manufacturing man-hour can be concentrated on the second layer, so that various semiconductor integrated circuit devices can be effectively realized at low cost.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of designing a semiconductor integrated circuit device, comprising the steps of:
designing a first layer which constitutes a portion including no pads of the semiconductor integrated circuit device, the first layer being used in common regardless of a package type of the semiconductor integrated circuit device; and
designing depending on the package type a second layer which constitutes a portion over the first layer of the semiconductor integrated circuit device.

2. The method according to claim 1, wherein, in a case of forming the pad on the semiconductor integrated circuit device, the pad is formed in the second layer.

3. The method according to claim 1, wherein an input/output buffer formed on the semiconductor integrated circuit device is formed only in the first layer.

4. The method according to claim 1, wherein an input/output buffer formed on the semiconductor integrated circuit device is formed in the first and second layers.

5. The method according to claim 1, wherein, in a case of forming on the semiconductor integrated circuit device the pad and a power reinforcing wire for connecting between the pad and a core of the semiconductor integrated circuit device, the pad and the wire are formed in the second layer.

6. The method according to claim 1, wherein, in a case of forming the pad on the semiconductor integrated circuit device, the pad and a wire for connecting between the pad and an input/output buffer formed on the semiconductor integrated circuit device are formed in the second layer.

7. The method according to claim 1, wherein, in a case of forming a bump on the semiconductor integrated circuit device, the bump and a wire connected with the bump are formed in the second layer.

8. A semiconductor integrated circuit device, comprising:
a first layer which constitutes a portion including no pads of the semiconductor integrated circuit device, the first layer being used in common regardless of a package type of the semiconductor integrated circuit device; and
a second layer which constitutes a portion over the first layer of the semiconductor integrated circuit device, the second layer being formed depending on the package type.

9. The device according to claim 8, wherein the pad is formed in the second layer.

10. The device according to claim 8, further comprising an input/output buffer, wherein the input/output buffer is formed only in the first layer.

11. The device according to claim 8, further comprising an input/output buffer, wherein the input/output buffer is formed in the first and second layers.

12. The device according to claim 8, further comprising the pad and a power reinforcing wire for connecting between the pad and a core and wherein the pad and the wire are formed in the second layer.

13. The device according to claim 8, further comprising the pad, an input/output buffer, and a wire for connecting between the pad and the input/output buffer, wherein the pad and the wire are formed in the second layer.

14. The device according to claim 8, further comprising a bump, an input/output buffer, and a wire connected with the bump, wherein the bump and the wire are formed in the second layer.

15. A method of manufacturing a semiconductor integrated circuit device, comprising the steps of:
forming a first layer which constitutes a portion including no pads of the semiconductor integrated circuit device, the first layer being used in common regardless of a package type of the semiconductor integrated circuit device; and
forming depending on the package type a second layer which constitutes a portion over the first layer of the semiconductor integrated circuit device.

16. The method according to claim 15, wherein, in the second layer forming step, the second layer is formed such that the pad is formed in the second layer.

17. The method according to claim 15, wherein, in the first and second layer forming steps, the first and second layers are formed such that an input/output buffer of the semiconductor integrated circuit device is formed only in the first layer or formed in the first and second layers.

18. The method according to claim 15, wherein, in the second layer forming step, the second layer is formed such that the pad and a power reinforcing wire for connecting between the pad and a core of the semiconductor integrated circuit device are formed in the second layer.

19. The method according to claim 15, wherein, in the second layer forming step, the second layer is formed such that the pad and a wire for connecting between the pad and an input/output buffer of the semiconductor integrated circuit device are formed in the second layer.

20. The method according to claim 15, wherein, in the second layer forming step, the second layer is formed such that a bump of the semiconductor integrated circuit device and a wire connected with the bump are formed in the second layer.
